(19) United States
(12) Patent Application Publication
(10) Pub. No.: US 2011/0299704 A1
(43) Pub. Date: Dec. 8, 2011

(54) Frequency-tracked synthesizer employing selective harmonic amplification and/or frequency scaling

(76) Inventor: Brian J. Kaczynski, San Francisco, CA (US)

(21) Appl. No.: 13/136,935

(22) Filed: Aug. 15, 2011

Related U.S. Application Data
(63) Continuation-in-part of application No. 11/728,121, filed on Mar. 23, 2007.

(51) Int. Cl. H03G 5/00; H03F 99/00

(52) U.S. Cl. 381/98; 381/120

(57) ABSTRACT

This invention relates to effects processing of a monophonic analog signal, meaning a signal whose frequency components are all integer multiples of a first fundamental frequency. For example, the signal could come from almost any musical instrument, voice included. However, for generality, the invention is not restricted to cases where the signal source is musical. The digital signal processing is simplified as a result of the DSP being clocked at a constant multiple of f_{fund}. This means that the sine and cosine functions, as well as the low-pass filters which make up each harmonic selector, are trivial to implement because the frequencies of each sine/cosine, as well as the cutoff frequency of the low-pass filters, are constant fractions of the DSP clock frequency.

### CROSS-REFERENCE TO RELATED APPLICATIONS

This application takes priority from U.S. patent application Ser. No. 11/728,121 filed Mar. 23, 2007.

### BACKGROUND OF THE INVENTION

1. Field of the Invention

The present invention relates generally to the field of analog and digital sound processing and more particularly to processing monophonic analog signals.

### BACKGROUND ART

This invention relates to effects processing of a monophonic analog signal (meaning a signal whose frequency components are all integer multiples of a first fundamental frequency). For example, the signal could come from almost any musical instrument, voice included. However, for generality, the invention is not restricted to cases where the signal source is musical.

The digital signal processing is simplified as a result of the DSP being clocked at a constant multiple of f_{fund}. This means that the sine and cosine functions, as well as the low-pass filters which make up each harmonic selector, are trivial to implement because the frequencies of each sine/cosine, as well as the cutoff frequency of the low-pass filters, are each constant fractions of the DSP clock frequency.

### SUMMARY OF THE INVENTION

An input analog signal is assumed to consist of a fundamental component and harmonic components which are concentrated at frequencies which are integer multiples of the fundamental frequency, for example, a musical note played by an instrument, sung by a human voice, etc. This input signal is low-pass filtered by an adaptive filter which allows the fundamental component to pass and attenuates the harmonic components. The resulting signal is passed through a limiter to generate a “reference” clock to a phase-locked loop (PLL). The PLL generates a clock whose frequency is a large multiple of the frequency of the original signal and this high-frequency clock is used to clock a digital signal processor (DSP).

In parallel with the process described above, the original input analog signal is digitized and then processed by the DSP whose clock frequency is generated, as described above, to be an integer multiple of the fundamental frequency of the analog signal. The signal is then decomposed into its individual harmonic components. Each harmonic is subjected to a selected gain or attenuation and optional frequency scaling, and then the modified harmonic components are summed to reconstitute an optionally frequency-scaled output signal with a different harmonic profile than that of the input. The final result is converted back to an analog signal with a D/A converter.

### BRIEF DESCRIPTION OF THE DRAWINGS

The various embodiments, features and advances of the present invention will be understood more completely hereinafter as a result of a detailed description thereof in which reference will be made to the following drawings:

FIG. 1 is a block diagram of a system for deriving the fundamental frequency of the input analog signal and employing an integer multiple of that frequency to clock a DSP system;

FIG. 2 is a block diagram of a fundamental frequency detector used in the system of FIG. 1; and

FIG. 3 is a block diagram of a frequency multiplier used in the preferred embodiment of the invention and comprising a phase-locked loop (PLL) with a loss of signal input;

FIG. 4 is a block diagram of a DSP system for selective harmonic amplification and/or frequency scaling and re-synthesis in accordance with the present invention;

FIG. 5 is a schematic representation of a selectively amplified and optionally frequency-scaled n-th harmonic (A (n)) of FIG. 4; and

FIG. 6 is a schematic representation of the re-synthesis of a modified output signal of the invention.

### DETAILED DESCRIPTION OF A PREFERRED EMBODIMENT

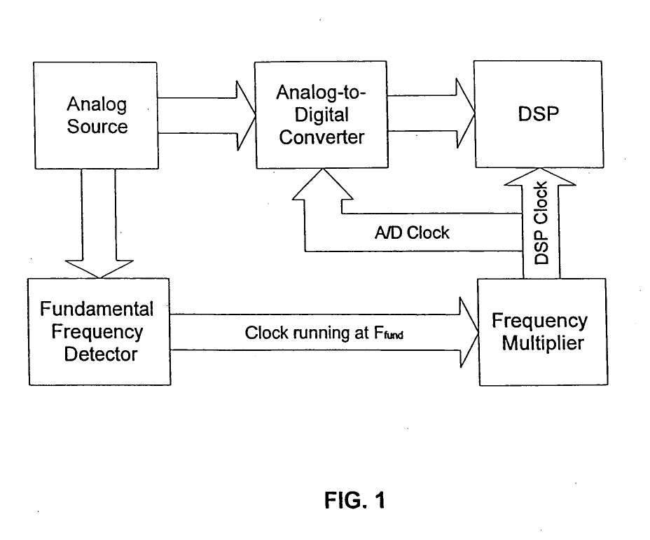

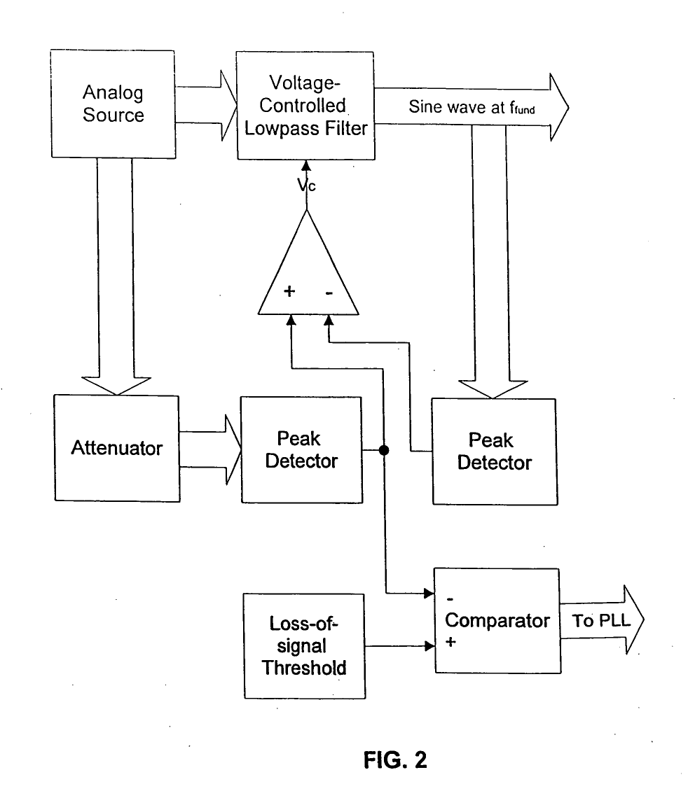

FIG. 1 illustrates a preferred embodiment which in its broadest sense comprises a detector for determining the fundamental frequency of the analog signal and a frequency multiplier for generating a clock signal having a frequency which is a precise constant multiple of the fundamental frequency. In further detail, the fundamental frequency tracking circuit may be implemented by passing the input signal through a voltage-controlled low-pass filter in a servo loop which forces a fixed amount of attenuation, as shown in FIG. 2. This loop is designed to sufficiently eliminate the higher-order harmonics present in the input signal in order to yield substantially a “sine wave” at the fundamental frequency of the input signal.

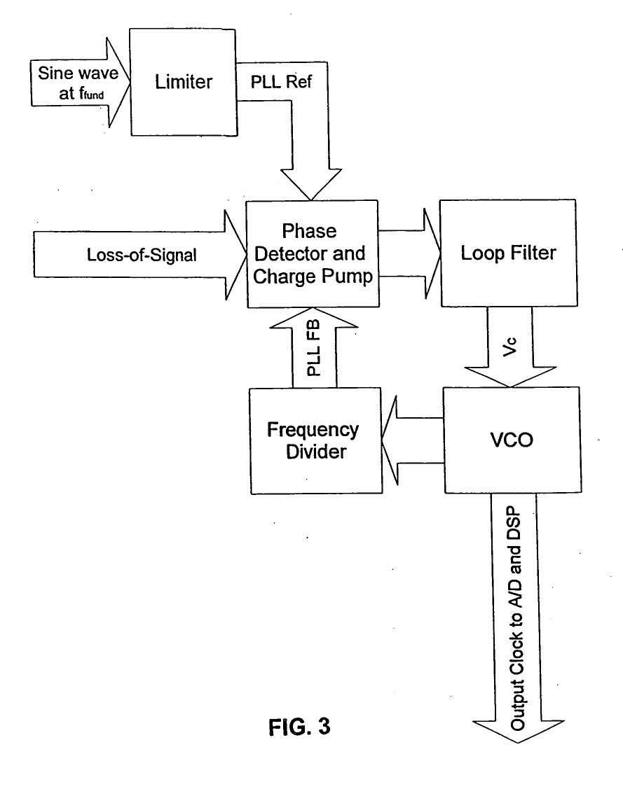

Further, the frequency-multiplying circuit necessary for generating the clock for the ND converter and DSP may be an analog or digital Phase-Locked Loop (PLL), an analog version of which is shown in FIG. 3. PLLs can be designed according to a known art and are well understood. The fundamental frequency detector, shown in FIG. 2, operates as follows: An input analog signal is attenuated and this attenuated signal is passed through a peak detector. The output of this peak detector represents a “reference signal”. The analog signal is also passed through a voltage-controlled low-pass filter and the output of this filter is passed through a second peak detector. The difference between the output of this second peak detector and the reference signal is amplified by an error amplifier and fed back as the control voltage to the filter. In the steady state, both peak detectors are outputting the same level, thus the low-pass filter has sufficiently eliminated the higher-order harmonics in the input analog signal so that the output of the voltage-controlled low-pass filter represents a sine wave at the fundamental frequency of the input analog signal.

A “threshold monitor” circuit shown in FIG. 2 generates a control signal to be output to the PLL. This circuit monitors the reference signal by comparing it to a fixed reference threshold. If the reference signal drops below this threshold value, the comparator outputs a “Loss of Signal” output which will disable the feedback action of the PLL in an attempt to “hold” the current locked frequency.

The PLL, shown in FIG. 3, has only one additional feature compared to the typical PLL. When the analog input signal gets too small and the “Loss of Signal” bit is set, the charge pump is disabled and the loop filter attempts to “hold” the current control voltage until the analog input signal returns to a healthy amplitude, and the PLL reference clock becomes valid again. Alternatively, an all-digital approach to the PLL could be considered in which the “Loss of Signal” signal would cause the PLL to “hold” the current frequency by alternative means.

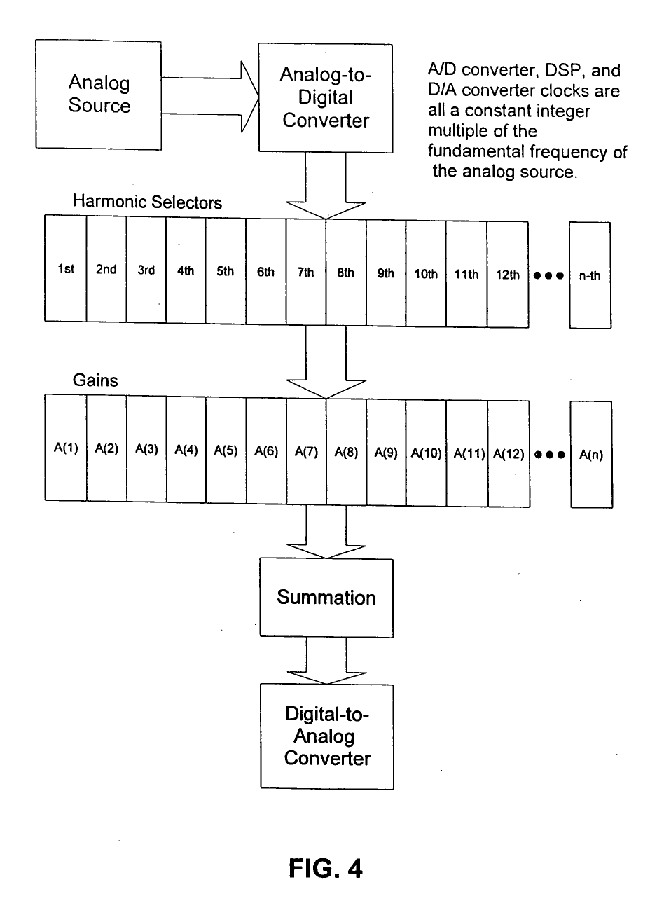

As shown in FIG. 4, the input analog signal is then digitized and processed by a DSP whose clock frequency is generated as described above to be an integer multiple of the fundamental frequency of the analog signal. The signal is then decomposed into its individual harmonic components. Each harmonic is subjected to a unique gain or attenuation, and then the modified harmonic components are summed to reconstitute an output signal with an optionally shifted frequency with respect to the original analog signal and a different harmonic profile than that of the input. The final result is converted back to an analog signal with a D/A converter. This converted result is the “output” of the effects processor.

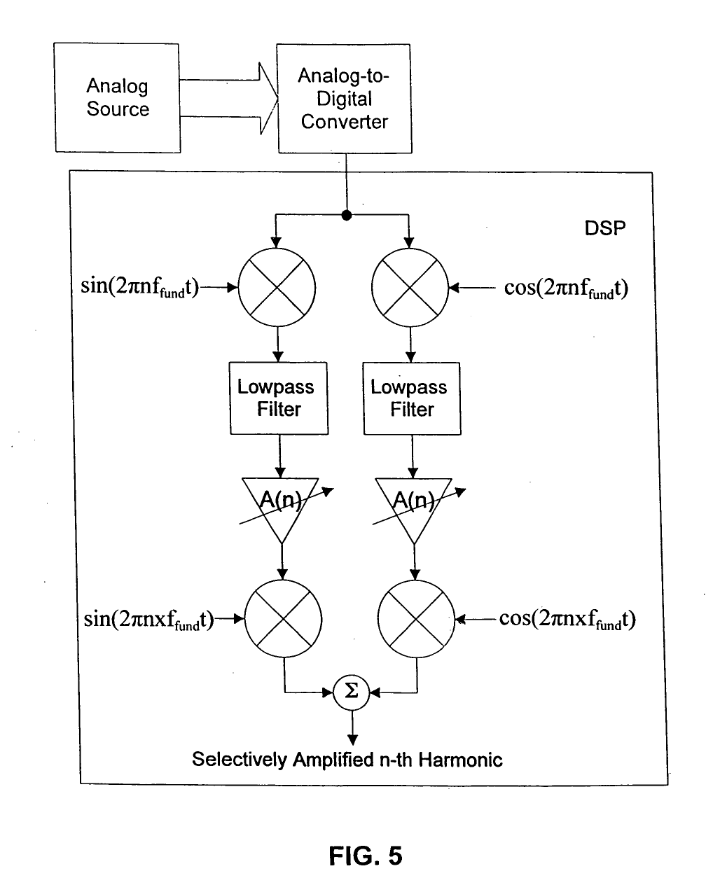

The extraction of an individual harmonic component (the “n-th” component, in this case) is shown in FIG. 5. This is done as follows: The n-th harmonic is mixed to DC in two separate paths. In the first path, the signal is multiplied by sin(2πnf_{fund}t), where f_{fund} is the fundamental frequency of the input signal. In the second path, the signal is multiplied by cos(2πf_{fund}t). These two “DC” signals are passed through low-pass filters to eliminate all other frequency content and to isolate the n-th harmonic. The only restriction on the cutoff frequency of these low-pass filters is that it must be less than f_{fund} in order to ensure that no other harmonics are present at this point in the signal path. Alternatively, the filter could be a simple boxcar average of the multiplier outputs over a period corresponding to 1/f_fund. Such a filter, combined with the sine/cosine multipliers, can be recognized as a simple FFT. Embodiments of the harmonic selector which utilize an FFT should be considered within the scope of the present invention. Next, these two DC signals are amplified (or attenuated) by programmable amounts A(n) which can be a function of n. Next, the signal which was generated by multiplying by sin(2πnf_{fund}t) is multiplied by sin(2πnxf_{fund}t) where “x” is the frequency scaling factor; the signal which was generated by multiplying by cos(2πnf_{fund}t) is multiplied by cos(2πnxf_{fund}t), where “x” is the frequency scaling factor; and these two results are summed together. Simple trigonometry reveals that if A(n)=2 and x=1 (no frequency scaling), the original signal is reconstructed at the output with no alterations.

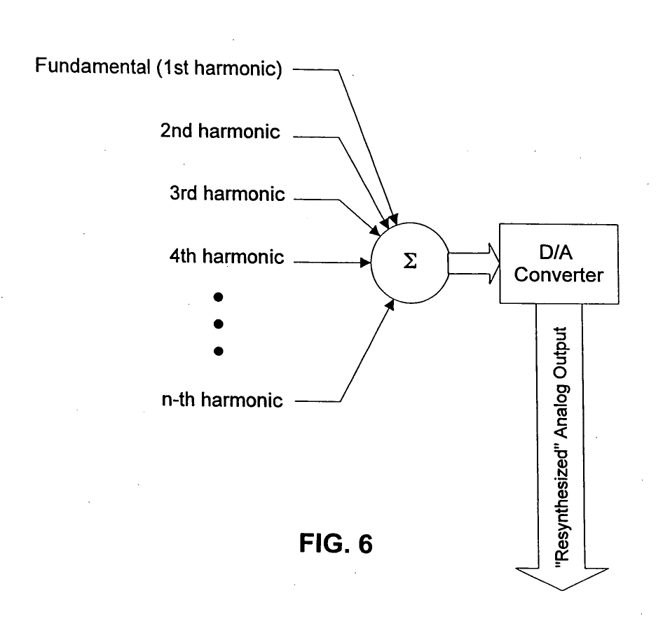

FIG. 6 illustrates the synthesis of the modified output signal. The outputs from all N harmonic “selectors” are summed together and the result is converted back into the analog domain using a D/A converter.

It cannot be sufficiently stressed how much the digital signal processing is simplified as a result of the DSP being clocked at a constant multiple of f_{fund}. This means that the sine and cosine functions, as well as the low-pass filters which make up each harmonic selector, are trivial to implement because the frequencies of each sine/cosine, as well as the cutoff frequency of the low-pass filters, are each constant fractions of the DSP clock frequency.

It is expected that creative selection of a signal source, and of the values of the A(n)'s, will yield interesting results. For example, if the input source is a human voice, and the harmonics are modified to resemble those of a violin, the output signal will have the attack and decay, in other words, the dynamics and agility/versatility of the human voice, but the harmonic timbre of a violin. It is evident that this method can be applied to transform the sound of any instrument into any other, or even into the sound of fictitious instruments that don't actually exist in material form. Additionally, the frequency scaling feature can shift the pitch of an instrument or voice, which can obviously be exploited to achieve a much wider variety of effects on the output audio signal.

Having thus disclosed a preferred embodiment of the present invention, it will now be seen that there may be various alternative ways for carrying out the invention, as well as certain modifications that could be made to the described embodiment while still realizing the advantageous features and benefits thereof. Therefore, the scope of protection sought herein should not necessarily be deemed to be limited by the disclosed embodiment. The invention hereof should be deemed to be defined only by the appended claims and their equivalents.

I claim:

1. A method of tracking the fundamental frequency of an analog signal for controlling the clock signal rate of a DSP system receiving the analog signal, to be a constant integer multiple of that fundamental frequency; the method comprising the steps of:
a) passing said analog signal to a fundamental frequency detector to generate a sine wave running at said fundamental frequency; and
b) applying said sine wave to a frequency multiplier to generate said clock signal.

2. The method recited in claim 1 further comprising the steps of c) connecting said analog signal to an analog-to-digital converter and d) clocking said analog-to-digital converter at said generated clock rate.

3. The method recited in claim 1 wherein step a) comprises the steps of:
c) applying the input analog signal to both a voltage-controlled low-pass filter and an attenuator;
d) connecting the output of the attenuator to a first peak detector to produce a reference signal;
e) connecting the output of the voltage-controlled low-pass filter to a second peak detector;
f) finding the difference between the reference signal and the output of the second peak detector and amplifying that difference; and
g) applying the amplified difference of step f) as the control voltage to the voltage controlled low-pass filter.

4. The method recited in claim 3 further comprising the steps of comparing said reference signal to a fixed reference threshold and generating a Loss of Signal output whenever the magnitude of a said reference signals falls below the magnitude of said threshold.

5. The method recited in claim 1 wherein step b) comprises the steps of:
applying said sine wave to a phase-locked loop containing a voltage-controlled oscillator and a frequency divider for locking the output frequency of the oscillator to the frequency of the sine wave as an integral multiple thereof.

6. The method recited in claim 4 wherein step b) comprises the steps of:
applying said sine wave to a phase locked loop containing a voltage-controlled oscillator and a frequency divider for locking the output frequency of the oscillator to the frequency of the sine wave as an integral multiple thereof;
wherein said phase-locked loop comprises a phase detector and a charge pump and a loop filter, said phase detector and charge pump receiving said Loss of Signal output for disabling said charge pump and causing said loop filter to hold a constant oscillator control voltage until the magnitude of said reference signal exceeds the magnitude of said threshold.

7. The method recited in claim 6 wherein said phase detector and said loop filter are implemented digitally.

8. An apparatus for tracking the fundamental frequency of an analog signal for controlling the clock signal rate of a DSP system receiving the analog signal, to be a constant integer multiple of that fundamental frequency; the apparatus comprising:
a fundamental frequency detector generating a sine wave running at said fundamental frequency; and
a frequency multiplier receiving said fundamental frequency sine wave and generating said clock signal of said DSP system therefrom.

9. The apparatus recited in claim 8 further comprising an analog-to-digital converter, said analog-to-digital converter being clocked by said clock signal.

10. The apparatus recited in claim 8 wherein said fundamental frequency detector comprises a voltage-controlled low-pass filter and an attenuator; and a first peak detector connected to said attenuator;
a second peak detector connected to the output of said voltage-controlled low-pass filter;
an amplifier connected to said first and second peak detectors for amplifying the difference between outputs of said peak detectors and connecting that amplified difference to said voltage-controlled low-pass filter.

11. The apparatus recited in claim 8 wherein said frequency multiplier comprises a phase-locked loop containing a voltage-controlled oscillator and a frequency divider locking the output frequency of said oscillator to the frequency of the sine wave as an integral multiple thereof.

12. In combination with a digital signal processor connected to an analog-to-digital converter for generating a digital representation of an analog signal to be acted upon by the digital signal processor; an apparatus for controlling a clock signal used by the digital signal processor, the apparatus comprising:
a detector for generating a sine wave having a frequency that is the fundamental frequency of said analog signal; and
a frequency multiplier for generating said clock signal at a frequency which is a precise selected multiple of said fundamental frequency of said sine wave.

13. In the combination recited in claim 12 the apparatus further comprising a voltage controlled low-pass filter producing said sine wave.

14. In the combination recited in claim 12 the apparatus further comprising a phase-locked loop having a voltage-controlled oscillator producing said clock signal.

15. In the combination recited in claim 12, the apparatus connecting said clock signal to said analog-to-digital converter as an A/D clock.

16. In the combination recited in claim 14, said phase-locked loop further comprising a Loss of Signal device for locking said voltage-controlled oscillator at its most recent frequency whenever said analog signal has a magnitude that falls below a selected threshold.

17. A digital signal processor receiving an analog signal and comprising a clock having an automatically alterable frequency, said clock frequency always being a constant multiple of the fundamental frequency of said analog signal.

18. A music synthesizer for modifying a monophonic analog signal having a fundamental frequency; the synthesizer comprising:
an analog-to-digital converter for digitizing said monophonic analog signal;
a plurality of harmonic selectors, each such selector having a filter for passing only a selected harmonic component of said digitized analog signal;
a plurality of amplifiers respectively connected to said harmonic selectors for applying selected levels of positive or negative gain to modify each of said harmonic components;
a summing device connected to said plurality of amplifiers for combining said modified harmonic components; and
a digital-to-analog converter for re-synthesizing an analog output from said combined, modified harmonic components,
wherein each said A/D converter, selector, amplifier and summing device is synchronized by a clock signal having a frequency which is a constant integer multiple of the fundamental frequency of said monophonic analog signal.

19. The music synthesizer recited in claim 18 wherein each of said harmonic selectors comprises at least one first mixer for mixing a selected harmonic component to DC and at least one low-pass filter to block all other harmonic components.

20. The music synthesizer recited in claim 19 wherein each said low-pass filter has a cutoff frequency which is less than said fundamental frequency.

21. The music synthesizer recited in claim 19 wherein each of said harmonic selectors comprises at least one second mixer for mixing said filtered harmonic component back to its original harmonic frequency or a shifted version thereof.

22. The music synthesizer recited in claim 19 wherein each said harmonic selector comprises two of said first mixers, said two first mixers each receiving a sine wave at said selected harmonic component frequency, but 90 degrees out of phase relative to each other.

23. The music synthesizer recited in claim 21 wherein each said harmonic selector comprises two of said second mixers, said two second mixers each receiving a sine wave at said selected harmonic component frequency, but 90 degrees out of phase, relative to each other.

24. The music synthesizer recited in claim 23 further comprising a summing junction receiving an output from each of said second mixers and combining them.

25. A method of modifying a monophonic analog signal having a fundamental frequency; the method comprising the steps of:
digitizing said monophonic analog signal;
splitting said digitized signal into its harmonic components;
applying a selected level of positive or negative gain to each of said harmonic components;
optionally shifting the frequencies of all components by a common factor;
summing said modified harmonic components;
converting said summed components into an analog signal; and
controlling a clock signal to have a frequency which is a constant integer multiple of the fundamental frequency of said monophonic analog signal.
